(19) United States
(12) Patent Application Publication
(10) Pub. No.: US 2015/0098281 A1
(43) Pub. Date: Apr. 9, 2015

(54) SEMICONDUCTOR CHIP AND SEMICONDUCTOR INTEGRATED CIRCUIT INCLUDING THE SAME

(71) Applicant: SK hynix Inc., Gyeonggi-do (KR)

(72) Inventors: Sang-Jin BYEON, Gyeonggi-do (KR); Jae-Bum KO, Gyeonggi-do (KR); Sang-Hoon SHIN, Gyeonggi-do (KR)

(73) Assignee: SK hynix Inc., Gyeonggi-do (KR)

(21) Appl. No.: 14/107,002

(22) Filed: Dec. 16, 2013

(30) Foreign Application Priority Data
Oct. 8, 2013 (KR) 10-2013-0119837

(51) Int. Cl. G11C 5/14

(52) U.S. Cl. CPC G11C 5/147
USPC 365/189.09; 327/540

(57) ABSTRACT

A semiconductor chip includes an internal voltage generation circuit suitable for generating an internal voltage having a predetermined level, a target internal circuit suitable for performing a predetermined operation using the internal voltage, and a control circuit suitable for checking operating speed of the target internal circuit based on an operation result signal generated from the target internal circuit, and generating the control signal based on the checked operating speed, wherein a voltage level of the internal voltage for target internal circuit is controlled based on the control signal.

### CROSS-REFERENCE TO RELATED APPLICATION

The present application claims priority of Korean Patent Application No. 10-2013-0119837 filed on Oct. 8, 2013, which is incorporated herein by reference in its entirety.

### BACKGROUND

1. Field

Exemplary embodiments of the present invention relate to semiconductor design technology, and more particularly, to a semiconductor chip using an internal voltage and a semiconductor integrated circuit (IC) including the same.

2. Description of the Related Art

In general, a two-dimensional (2-D) structured semiconductor IC packaged to include one semiconductor chip shows the limit in improving the degree of integration. In order to increase the degree of integration, a three-dimensional (3-D) structured semiconductor IC packaged to include a plurality of semiconductor chips is proposed. A 3-D structured semiconductor IC may realize a maximum degree of integration within the same space by vertically stacking a plurality of semiconductor chips. Such a 3-D structured semiconductor IC includes a plurality of regions, and the regions each operate independently. A memory device, such as a dynamic random access memory (DRAM), is described below as an example.

FIG. 1 is a diagram conceptually illustrating a plurality of regions included in a conventional 3-D structured memory device.

Referring to FIG. 1, memory devices 10, 20, and 30 each may include memory regions and control circuits for controlling the operations of the memory regions. The memory regions may include a memory region of a higher concept, and the memory region of a in higher concept may include memory regions of a lower concept.

As shown in FIG. 1(A), the memory device 10 may include a plurality of channels CH0 to CHy and a control circuit for channel CH_CTRL for controlling the operations of the channels CH0 to CHy. Each of the channels CH0 to CHy may include a plurality of ranks RK0 to RKx and a control circuit for rank RK_CTRL for controlling the ranks RK0 to RKx. Each of the ranks RK0 to RKx may include a plurality of bank groups BG0 to BGm and a control circuit for bank group BG_CTRL for controlling the bank groups BG0 to BGm. Each of the bank groups BG0 to BGm may include a plurality of banks BK0 to BKn and a control circuit for bank BK_CTRL for controlling the banks BK0 to BKn. Here, each of notations m, n, x, and y may be an integer.

As shown in FIG. 1 (B), the memory device 20 may include a plurality of ranks RK0 to RKx and a control circuit for rank RK_CTRL for controlling the operations of the ranks RK0 to RKx. Each of the ranks RK0 to RKx may include a plurality of bank groups BG0 to BGm and a control circuit for bank group BG_CTRL for controlling the operations of the bank groups BG0 to BGm. Each of the bank groups BG0 to BGm may include a plurality of banks BK0 to BKn and a control circuit for bank BK_CTRL for controlling the banks BK0 to BKn.

As shown in FIG. 1 (C), the memory device 30 may include a plurality of bank groups BG0 to BGm and a control circuit for bank group BG_CTRL for controlling the banks BG0 to BGm. Each of the bank groups BG0 to BGm may include a plurality of banks BK0 to BKn and a control circuit for bank BK_CTRL for controlling the bank groups BG0 to BGm.

As described above, the memory devices 10, 20, and 30 may selectively include a channel, a rank, and a bank group as memory regions having a higher concept and may selectively include a rank, a bank group, and a bank as memory regions having a lower concept.

However, such a conventional 3-D structured memory device has a concern in that there may be a difference in the asynchronous operating speed between memory regions if the memory regions have different process, voltage, and temperature (PVT) characteristics. Furthermore the overall operating speed of the memory device may be reduced because the operating speed is tuned into the lowest operating speed when the operating speed of each memory region is synchronized.

### SUMMARY

Various embodiments are directed to a semiconductor chip in which operating speed may be controlled and synchronization may be performed for each region, and a semiconductor IC including the same.

In an embodiment, a semiconductor chip may include an internal voltage generation circuit suitable for generating an internal voltage having a predetermined level, a target internal circuit suitable for performing a predetermined operation using the internal voltage, and a control circuit suitable for checking operating speed of the target internal circuit based on an operation result signal generated from the target internal circuit, and generating the control signal based on a result of the check, wherein a voltage level of the internal voltage for target internal circuit is controlled based on the control signal.

In an embodiment, a semiconductor chip may include a plurality of internal voltage generation circuits suitable for generating a plurality of internal voltages and controlling voltage levels of the internal voltages based on a plurality of control signals, respectively, a plurality of memory regions suitable for performing data read operations using the respective internal voltages, and a control circuit suitable for checking operating speeds of the respective memory regions based on a plurality of data read from the memory regions, and generating the control signals based on the respective checked operating speeds.

In an embodiment, a semiconductor IC with a plurality of stacked semiconductor chips may include: a first semiconductor chip including a plurality of first internal voltage generation circuits suitable for generating a plurality of first internal voltages to be supplied to respective first memory regions, respectively, and controlling voltage levels of the first internal voltages based on a plurality of first control signals, and a plurality of first memory regions suitable for performing data read operations using the first internal voltages; a second semiconductor chip including a plurality of second internal voltage generation circuits suitable for generating a plurality of second internal voltages to be supplied to respective second memory regions, respectively, and controlling voltage levels of the second internal voltages based on a plurality of second control signals, and a plurality of second memory regions suitable for performing data read operations using the second internal voltages; and a third semiconductor chip including a control circuit suitable for checking operating speeds of the respective first and second memory regions based on a plurality of first data read from the first semiconductor chip and a plurality of second data read from the second semiconductor chip, and generating the first and second control signals based on the respective checked operating speeds.

### BRIEF DESCRIPTION OF THE DRAWINGS

FIG. 1 is a diagram conceptually illustrating a plurality of regions included in a 3-D structured semiconductor integrated circuit (IC).

FIG. 2 is a diagram illustrating a 3D structured semiconductor IC in accordance with a first embodiment of the present invention.

FIG. 3 is a detailed diagram of an example of a first memory chip shown in FIG. 2.

FIG. 4 is a detailed diagram of a control circuit shown in FIG. 3.

FIG. 5 is a detailed diagram of another example of the first memory chip shown in FIG. 2.

FIG. 6 is a diagram illustrating a 3D structured semiconductor IC in accordance with a second embodiment of the present invention.

FIG. 7 is a detailed diagram of a control chip and first and second memory chips shown in FIG. 6.

FIGS. 8 and 9 are diagrams for explaining the control of a plurality of memory regions included in the 3D structured semiconductor IC shown in FIG. 7.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention.

The drawings are not necessarily to scale and in some instances, proportions may have been exaggerated to dearly illustrate features of the embodiments. In this specification, specific terms have been used. The terms are used to describe the present invention, and are not used to qualify the sense or limit the scope of the present invention.

It is also noted that in this specification, ‘and/or’ represents that one or more of components arranged before and after ‘and/or’ is included. Furthermore, “connected/coupled” refers to one component not only directly coupling another component but also indirectly coupling another component through an intermediate component. In addition, a singular form may include a plural form as long as it is not specifically mentioned in a sentence. Furthermore, ‘include/comprise’ or ‘including/comprising’ used in the specification represents that one or more components, steps, operations, and elements exist or are added.

A semiconductor IC in accordance with an embodiment of the present invention is described by taking a memory device, such as DRAM, as an example.

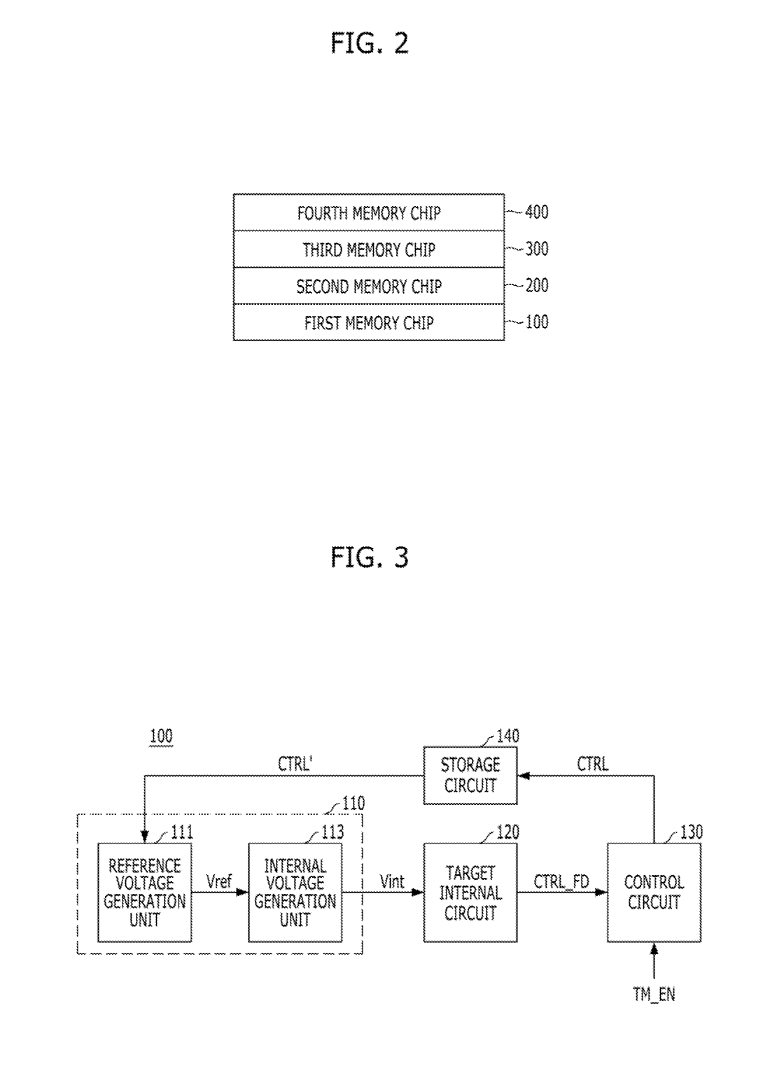

FIG. 2 is a diagram illustrating a 3D structured semiconductor IC in accordance with an embodiment of the present invention.

Referring to FIG. 2, the 3-D structured semiconductor IC may include first to fourth memory chips 100 to 400 that are vertically stacked. The first to the fourth memory chips 100 to 400 may be homogeneous or heterogeneous chips. It is hereinafter assumed that the first to the fourth memory chips are homogeneous chips for convenience of description, and only the first memory chip 100 is described as a representative example.

FIG. 3 is a detailed diagram of an example of the first memory chip 100 shown in FIG. 2.

Referring to FIG. 3, the first memory chip 100 may include an internal voltage generation circuit 110 for generating an internal voltage Vint having a predetermined level in response to a control signal CTRL′, a target internal circuit 120 for performing a predetermined operation using the internal voltage Vint, a control circuit 130 for checking operating speed of the target internal circuit 120 based on an operation result signal CTRL_FD generated from the target internal circuit 120 in a test mode and generating a control signal CTRL based on a result of the check, and a storage circuit 140 for storing the control signal CTRL.

The internal voltage generation circuit 110 may include a reference voltage generation unit 111 for generating a reference voltage Vref whose voltage level is controlled in response to the control signal CTRL′ and an internal voltage generation unit 113 for generating the internal voltage Vint corresponding to the reference voltage Vref.

The target internal circuit 120 may include a plurality of memory regions and may perform a predetermined operation under the control of the control circuit 130 in the test mode or perform a predetermined operation under the control of an external controller (not shown).

The control circuit 130 may control the overall operations of the internal voltage generation circuit 110, the target internal circuit 120, and the storage circuit 140 in response to a test mode signal TM_EN. The test mode signal TM_EN may be generated in response to an address signal related to the test mode.

Furthermore, the storage circuit 140 may include a register circuit or a fuse circuit.

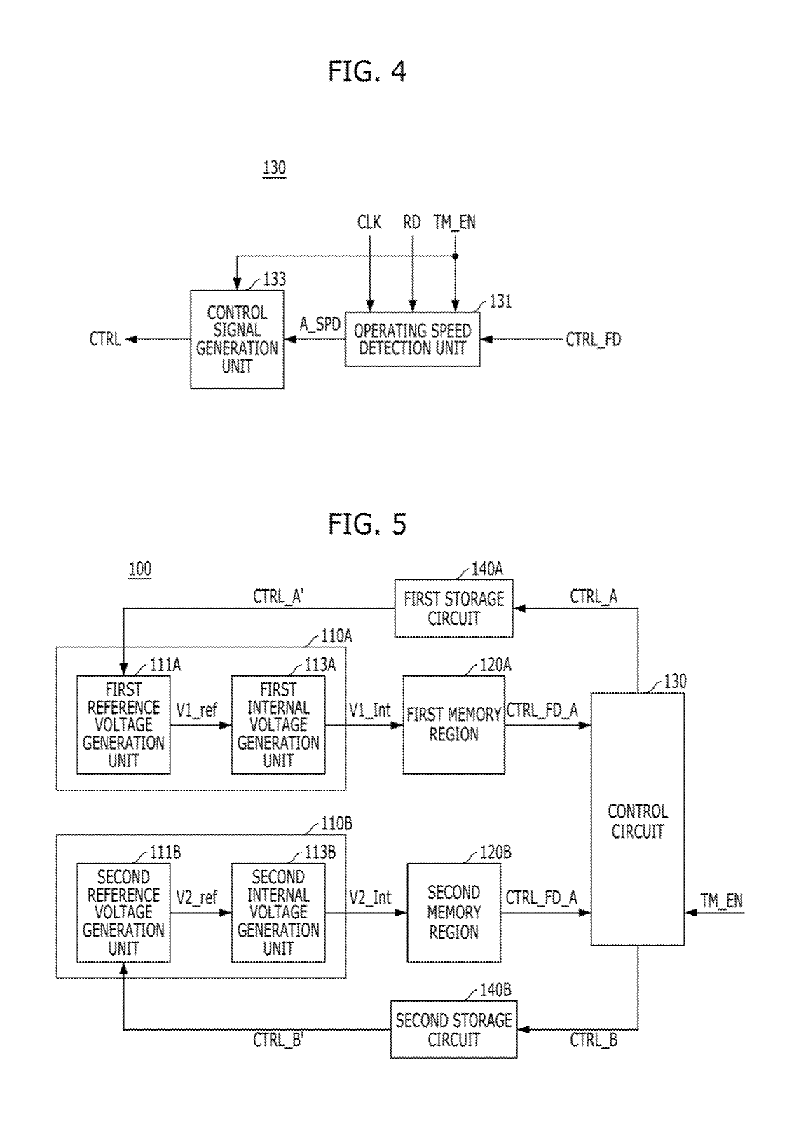

FIG. 4 is a detailed diagram of the control circuit 130 shown in FIG. 3.

Referring to FIG. 4, the control′ circuit 130 may include an operating speed detection unit 131 for detecting operating speed of the target internal circuit 120 in response to the test mode signal TM_EN, a clock CLK, and an operation start signal RD and the operation result signal CTRL_FD generated from the target internal circuit 120 and a control signal generation unit 133 for generating the control signal CTRL in response to an operating speed detection signal A_SPD generated from the operating speed detection unit 131. For example, the operating speed detection unit 131 may measure an operating time from a point in time where the operation start signal RD is received to a point in time where the operation result signal CTRL_FD is output and detect operating speed of the target internal circuit 120 based on the measured operating time. Furthermore, the control signal generation unit 133 may compare operating speed, detected by the operating speed detection unit 131, with a predetermined reference speed and generate the control signal CTRL corresponding to a result of the comparison. Here, the operation start signal RD may be received from an external controller or the control circuit 130 in the test mode.

FIG. 5 is a detailed diagram of another example of the first memory chip 100 shown in FIG. 2. In FIG. 5, the same or similar reference numerals are assigned to elements corresponding to those of FIG. 3.

Referring to FIG. 5 the first memory chip 100 may include first and second internal voltage generation circuits 110A and 110B for generating first and second internal voltages V1_Int and V2_Int to be supplied to first and second memory regions 120A and 120B and controlling voltage levels of the first and the second internal voltages V1_Int and V2_Int in response to first and second control signals CTRL_A′ and CTRL_B′, first and second memory regions 120A and 120B for performing a data read operation using the first and the second internal voltages V1_Int and V2_Int, a control circuit 130 for checking operating speed of each of the first and the second memory regions 120A and 120B based on first and read data CTRL_FD_A and CTRL_FD_B read from the first and the second memory region 120A and 120B and generating first and second control signals CTRL_A and CTRL_B based on a result of the check, and first and second storage circuits 140A and 140B for storing the first and the second control signals CTRL_A and CTRL_B.

The first internal voltage generation circuit 110A may include a first reference voltage generation unit 111A for generating a first reference voltage V1_ref whose a voltage level is controlled in response to the first control signal CTRL_A′ and a first internal voltage generation unit 113A for generating the first internal voltage V1_Int corresponding to the first reference voltage V1_ref. Furthermore, the second internal voltage generation circuit 110B may include a second reference voltage generation unit 111B for generating a second reference voltage V2_ref whose voltage level is controlled in response to the second control signal CTRL_B′ and a second internal voltage generation unit 113B for generating the second internal voltage V2_Int corresponding to the second reference voltage V2_ref. In the present embodiment, the two internal voltage generation circuits 110A and 110E have been illustrated as being included in the first memory chip 100, but the present invention is not limited thereto. The first memory chip 100 may include three or more internal voltage generation circuits. In such a case, the number of internal voltage generation circuits may correspond to the number of memory regions.

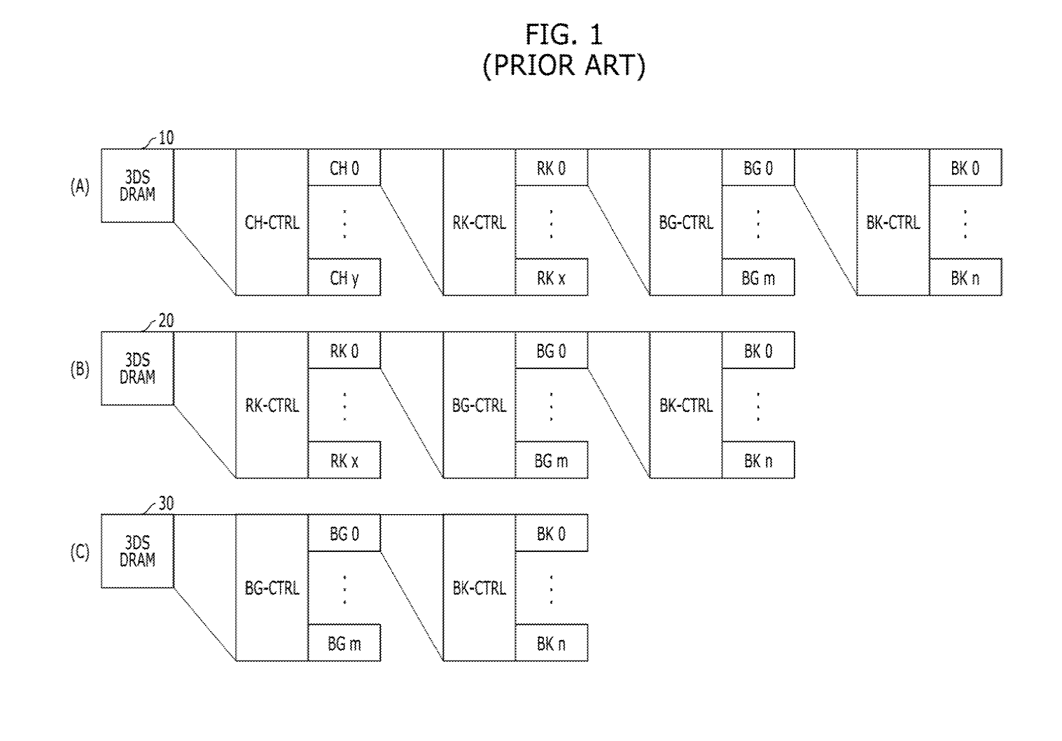

Furthermore, the first and the second memory regions 120A and 120B may selectively include a channel, a rank, and a bank group (refer to FIG. 1).

Meanwhile, the control circuit 130 and the first and the second storage circuits 140A and 140B have the same constructions as those of FIGS. 3 and 4, and thus a description thereof is omitted. However, the operating speed detection unit 131 of the control circuit 130 may measure an operating time, for example, data access time (as referred to tAA) from a point in time where the operation start signal RD, for example, a read command, is received to a point in time where the first read data CTRL_FD_A or the second read data CTRL_FD_B is output through a data pad (not shown) and detect the operating speed of the memory region based on the measured operating time.

The operation of the semiconductor IC in accordance with the first embodiment of the present invention is described below.

When the test mode signal TM_EN is activated and the test mode is entered, the first and the second memory regions 120A and 120B may perform data read operations using the first and the second internal voltages V1_Int and V2_Int in response to the read command RD (refer FIG. 4) and generate the first and the read data CTRL_FD_A and CTRL_FD_B corresponding to the data read operations.

The control circuit 130 may check operating speeds of the first and the second memory regions 120A and 120B based on the first and the read data CTRL_FD_A and CTRL_FD_B. For example, the control circuit 130 may measure the operating time tAA from a point in time where the read command RD is received to a point in time where the first and the read data CTRL_FD_A and CTRL_FD_B are output through the data pad (not shown) and detect the operating speeds of the first and the second memory regions 120A and 120B based on the measured operating time.

Furthermore, the control circuit 130 may generate the first and the second control signals CTRL_A and CTRL_B based on the checked operating speeds. For example, the control circuit 130 may generate the first control signal CTRL_A corresponding to a high-speed operation if the checked operating speed of the first memory region 120A is slower than a predetermined reference speed and may generate the second control signal CTRL_B corresponding to a low-speed operation if the checked operating speed of the second memory region 120B is faster than the predetermined reference speed.

The first internal voltage generation circuit 110A may generate the first internal voltage V1_Int corresponding to the control signal CTRL′_A and supply the first internal voltage V1_Int to the first memory region 120A. More particularly, the first reference voltage generation unit 111A controls the first reference voltage V1_ref in response to the first control signal CTRL_A′. The first internal voltage generation unit 113A may generate the first internal voltage V1_Int corresponding to the first reference voltage V1_ref and supply the first internal voltage V1_Int to the first memory region 120A. For example, if the first reference voltage generation unit 111A controls the first reference voltage V1_ref in response to the first control signal CTRL_A′ so that the first reference voltage V1_ref has a voltage level higher than a previous voltage level, the first internal voltage generation unit 113A generates the first internal voltage V1_Int having a voltage level higher than a previous voltage level in accordance with the first reference voltage V1_ref having the higher voltage level.

Furthermore, the second internal voltage generation circuit 110B may generate the second internal voltage V2_Int in response to the control signal CTRL_B′ and supply the second internal voltage V2_Int to the second memory region 120B. More particularly, the second reference voltage generation unit 111B controls the second reference voltage V2 ref in response to the second control signal CTRL_B′. The second internal voltage generation unit 113B may generate the second internal voltage V2_Int corresponding to the second reference voltage V2_ref and supply the second internal voltage V2_Int to the second memory region 120B. For example, if the second reference voltage generation unit 111B controls the second reference voltage V2_ref in response to the second control signal CTRL_B′ so that the second reference voltage V2_ref has a voltage level lower than a previous voltage level, the second internal voltage generation unit 113B generates the second internal voltage V2_Int having a voltage level lower than a previous voltage level in accordance with the second reference voltage V2_ref having the lower voltage level.

The first and the second memory regions 120A and 120B may perform data read operations using the first and the second internal voltages V1_Int and V2_Int in response to the read command RD and supply the control circuit 130 with the first and the read data CTRL_FD_A and CTRL_FD_B corresponding to the data read operations.

In response thereto, the control circuit 130 may check operating speeds of the first and the second memory regions 120A and 120B based on the first and the read data CTRL_FD_A and CTRL_FD_B and generate the first and the second control signal CTRL_A and CTRL_B corresponding to results of the check.

The operating speeds of the first and the second memory regions 120A and 120B are synchronized with each other by repeatedly performing a series of the processes under the control of the control circuit 130.

Meanwhile, when optimum operating speeds of the first and the second storage circuits 140A and 140B are checked, the first and the second storage circuits 140A and 1405 may store information about the first and the second control signals CTRL_A and CTRL_B, corresponding to the optimum operating speeds, in the first and the second storage circuits 140A and 140B.

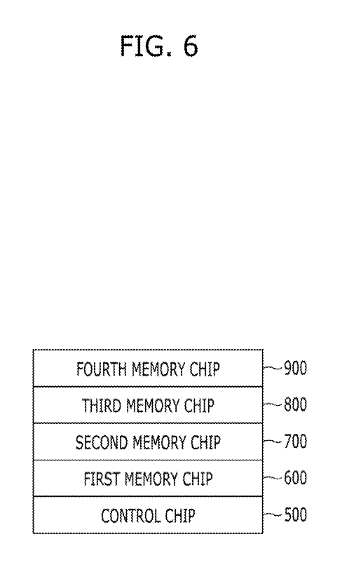

FIG. 6 is a diagram illustrating a 3D structured semiconductor IC in accordance with another embodiment of the present invention.

The 3D structured semiconductor IC in accordance with the second embodiment: of the present invention differs from the 3D structured semiconductor IC of the first embodiment in that a control circuit is included in an additional chip.

Referring to FIG. 6, the 3D structured semiconductor IC may include one control chip 500 and first to fourth memory chips 600 to 900 and has a structure in which the first to the fourth memory chips 600 to 900 are vertically stacked over the control chip 500. Order that the chips 500 to 900 are stacked is not limited to that of FIG. 6, but may be changed depending on the designer.

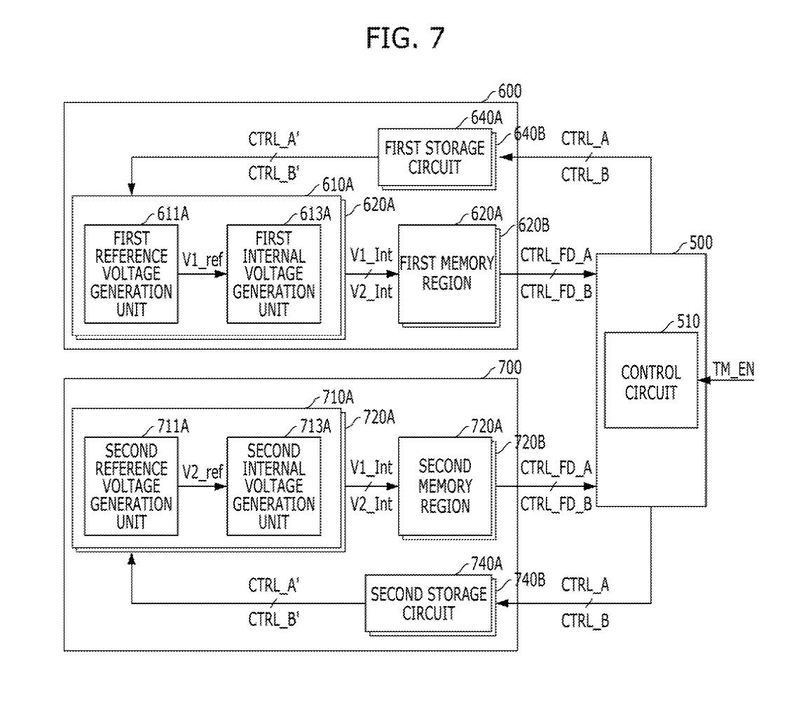

FIG. 7 is a detailed diagram of the control chip 500 and the first and the second memory chips 600 and 700 shown in FIG. 6. It is to be noted that only the first and the second memory chips 600 and 700 of the first to the fourth memory chips 600 to 900 are illustrated in FIG. 7, for convenience of description.

Referring to FIG. 7, the first memory chip 600 may include first and second internal voltage generation circuits 610A and 6106 for generating first and second internal voltages V1_Int and V2_Int to be supplied to first and second memory regions 620A and 620B and controlling voltage levels of the first and the second internal voltages V1_Int and V2_Int in response to first and second control signals CTRL_A and CTRL_B′ and the first and the second memory regions 620A and 620B for performing data read operations using the first and the second internal voltages V1_Int and V2_Int.

The second memory chip 700 may include first and second internal voltage generation circuits 710A and 710B for generating first and second internal voltages V1_Int and V2_Int to be supplied to first and second memory regions 720A and 720B and controlling voltage levels of the first and the second internal voltages V1_Int and V2_Int in response to the first and the second control signals CTRL_A′ and CTRL_B′ and the first and the second memory regions 720A and 720B for performing data read operations using the first and the second internal voltages V1_Int and V2_Int.

The control chip 500 may include a control circuit 510 for checking operating speeds of the first and second memory regions (620A, 620B) and (720A, 720B) based on a plurality of first and read data CTRL_FDA and CTRL_FD_B generated from the first and the second semiconductor chips 600 and 700 and generating the first and second control signals CTRL_A′ and CTRL_B′ based on results of the check.

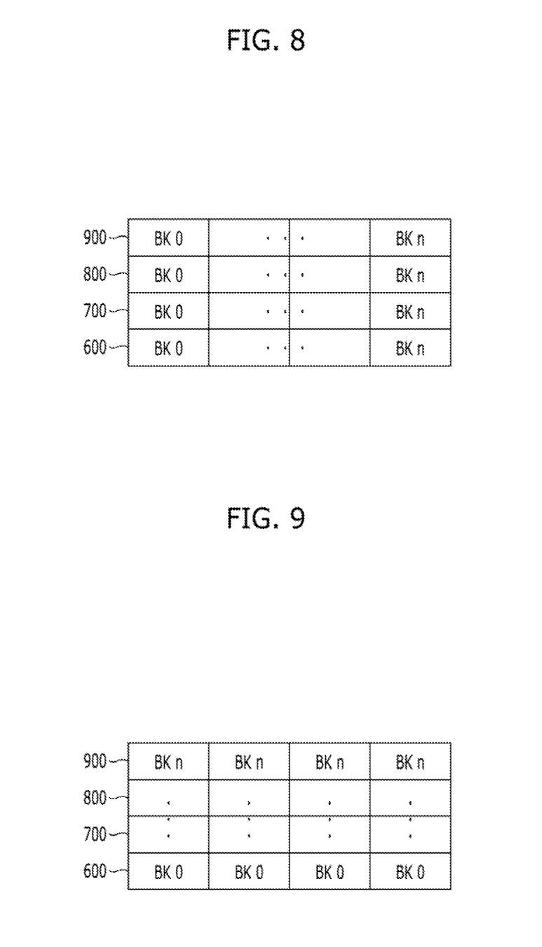

The control circuit 510 of the control chip 500 is the same as the control circuit 130 of the first embodiment of the present invention, the first and the second internal voltage generation circuits 610A and 610B, the first and the second memory regions 620A and 620B, and the first and the second storage circuits 640A and 640B of the first memory chip 600 are the same as those (110A, 110B), (120A, 120B), and (140A, 140B) of the first embodiment of the present invention, and the first and the second internal voltage generation circuits 710A and 710B, the first and the second memory regions 720A and 720B, and the first and the second storage circuits 740A and 7408 of the second memory chip 700 are also the same as those (110A, 110B), (120A, 120B), and (140A, 140B) of the first embodiment of the present invention. Accordingly, a description of the constructions and operations of the same elements is omitted for simplicity. In the second embodiment of the present invention, synchronization may be performed on each memory chip, that is, operating speeds of memory regions, for example, banks BK, in a horizontal direction (refer to FIG. 8) as in the first embodiment, and synchronization may also be performed on operating speeds of memory regions, for example, banks BK, in a vertical direction (refer to FIG. 9).

In accordance with the embodiments of the present invention, operating speeds of memory regions may be synchronized with each other and the memory regions may be synchronized with a desired operating speed.

In accordance with the embodiments of the present invention, operating speed has been checked regarding an actual path, but the present invention is not limited thereto. For example, operating speed may be checked regarding a replica path modeled from an actual path.

As described above, operating speeds of memory regions may be synchronized with each other irrespective of process, voltage, and temperature (PVT) characteristics by controlling an internal voltage supplied to each memory region. Accordingly, there is an advantage in that performance of a semiconductor IC may be improved.

Although various embodiments have been described for illustrative purposes, it will be apparent to those skilled in the art that various changes and modifications may be made without departing from the spirit and scope of the invention as defined in the following claims.

What is claimed is:

1. A semiconductor chip, comprising:
an internal voltage generation circuit suitable for generating an internal voltage having a predetermined level;
a target internal circuit suitable for performing a predetermined operation using the internal voltage; and
a control circuit suitable for checking operating speed of the target internal circuit based on an operation result signal generated from the target internal circuit, and generating the control signal based on the checked operating speed,
wherein a voltage level of the internal voltage for target internal circuit is controlled based on the control signal.

2. The semiconductor chip of claim 1, wherein the control circuit comprises:
an operating speed detection unit suitable for detecting the operating speed based on an operation start signal and the operation result signal of the target internal circuit, and generating an operating speed detection signal corresponding to the detected operating speed, in a test mode; and
a control signal generation unit suitable for generating the control signal based on the operating speed detection signal in the test mode.

3. The semiconductor chip of claim 2, wherein the operation start signal is received externally in the test mode or generated from the control circuit.

4. The semiconductor chip of claim 1, further comprising a storage circuit suitable for storing the control signal.

5. The semiconductor chip of claim 4, wherein the storage circuit comprises a register circuit or a fuse circuit.

6. The semiconductor chip of claim 1, wherein the internal voltage generation circuit comprises:
a reference voltage generation unit suitable for generating a reference voltage having a voltage level controlled based on the control signal; and
an internal voltage generation unit suitable for the internal voltage corresponding to the reference voltage.

7. A semiconductor chip, comprising:
a plurality of internal voltage generation circuits suitable for generating a plurality of internal voltages and controlling voltage levels of the internal voltages based on a plurality of control signals, respectively;
a plurality of memory regions suitable for performing data read operations using the respective internal voltages; and
a control circuit suitable for checking operating speeds of the respective memory regions based on a plurality of data read from the memory regions, and generating the control signals based on the respective checked operating speeds.

8. The semiconductor chip of claim 7, wherein the control circuit comprises:
an operating speed detection unit suitable for detecting the operating speeds based on a read command and the respective read data, and generating a plurality of operating speed detection signals corresponding to the respective read data, in a test mode; and
a control signal generation unit suitable for generating the control signals based on the respective operating speed detection signals.

9. The semiconductor chip of claim 8, wherein the read command is received externally in the test mode or generated from the control circuit.

10. The semiconductor chip of claim 7, wherein each of the internal voltage generation circuits comprises:
a reference voltage generation unit suitable for generating a corresponding reference voltage having a voltage level controlled based on a corresponding control signal; and
an internal voltage generation unit suitable for generating a corresponding internal voltage according to the corresponding reference voltage.

11. The semiconductor chip of claim 7, further comprising a plurality of storage circuits suitable for storing the control signals, respectively.

12. The semiconductor chip of claim 11, wherein each of the storage circuits comprises a register circuit or a fuse circuit.

13. The semiconductor chip of claim 7, wherein each of the memory regions comprise any one of a bank, a bank group, a rank, and a channel.

14. A semiconductor IC with a plurality of stacked semiconductor chips, comprising:
a first semiconductor chip including a plurality of first internal voltage generation circuits suitable for generating a plurality of first internal voltages to be supplied to respective first memory regions, respectively, and controlling voltage levels of the first internal voltages based on a plurality of first control signals, and a plurality of first memory regions suitable for performing data read operations using the first internal voltages;
a second semiconductor chip including a plurality of second internal voltage generation circuits suitable for generating a plurality of second internal voltages to be supplied to respective second memory regions, respectively, and controlling voltage levels of the second internal voltages based on a plurality of second control signals, and a plurality of second memory regions suitable for performing data read operations using the second internal voltages; and
a third semiconductor chip including a control circuit suitable for checking operating speeds of the respective first and second memory regions based on a plurality of first data read from the first semiconductor chip and a plurality of second data read from the second semiconductor chip, and generating the first and second control signals based on the respective checked operating speeds.

15. The semiconductor chip of claim 14, wherein the control circuit comprises:
an operating speed detection unit suitable for detecting the respective operating speeds based on a read command, the respective read first data, and the respective read second data, and generating a plurality of operating speed detection signals corresponding to the respective read first data and the respective read second data, in a test mode; and
a control signal generation unit suitable for generating the first and second control signals based on the respective operating speed detection signals.

16. The semiconductor chip of claim 15, wherein the read command is received externally in the test mode or generated from the control circuit.

17. The semiconductor chip of claim 14, wherein each of the first internal voltage generation circuits comprises:
a first reference voltage generation unit suitable for generating a corresponding first reference voltage having a voltage level controlled based on a corresponding first control signal; and
a first internal voltage generation unit suitable for generating the a corresponding first internal voltage according to the corresponding first reference voltage.

18. The semiconductor chip of claim 17, wherein each of the second internal voltage generation circuits comprises:
a second reference voltage generation unit suitable for generating a corresponding second reference voltage having a voltage level controlled based on a corresponding second control signal; and
a second internal voltage generation unit suitable for generating a corresponding second internal voltage according to the corresponding second reference voltage.
